(19) United States
(12) Patent Application Publication
(10) Pub. No.: US 2024/0393375 A1
(43) Pub. Date: Nov. 28, 2024

(54) POWER RECEPTION APPARATUS AND RECEIVED POWER ESTIMATION METHOD

(71) Applicant: Panasonic Holdings Corporation, Osaka (JP)

(72) Inventors: MANABU GOKAN, Hyogo (JP); YUKI TANAKA, Tokyo (JP); TAKUMA IKEDA, Osaka (JP); AYA KUROKAWA, Osaka (JP); HIROYUKI TANI, Hyogo (JP)

(21) Appl. No.: 18/795,243

(22) Filed: Aug. 6, 2024

Related U.S. Application Data
(63) Continuation of application No. PCT/JP2022/027645, filed on Jul. 14, 2022.

(30) Foreign Application Priority Data
Feb. 25, 2022 (JP) 2022-027858

(51) Int. Cl. G01R 19/22; H02J 50/20; H02J 50/40

(52) U.S. Cl. CPC G01R 19/22; H02J 50/20; H02J 50/40

(57) ABSTRACT

A power reception apparatus includes a main rectifier circuit unit that rectifies received power and outputs rectified power to a load, a sub rectifier circuit unit connected in parallel with a power reception unit of the main rectifier circuit unit, and a measurement unit that measures power of an output unit of the sub rectifier circuit unit.

### TECHNICAL FIELD

The present disclosure relates to a power reception apparatus and a received power estimation method.

### BACKGROUND ART

A wireless power transmission system capable of wirelessly transmitting power has conventionally been known. In the wireless power transmission system, practical application of the system to which a microwave wireless power feeding technology for Internet of Things (IoT) is applied has also been studied, for example.

In the power reception apparatus of such a wireless power transmission system, an efficient operation can be performed by observing the received power amount in real time. In addition, the amount of transmitted power can be maintained at a necessary and sufficient level by feeding back the information of the received power to the power transmission apparatus.

As a conventional method for measuring a received power amount, a method of directly measuring input power and a method of directly measuring output power of a rectifier circuit are known. For example, PTL 1 discloses a configuration for measuring an input power amount at a measurement point between a power reception unit and a rectifier unit.

### CITATION LIST

### Patent Literature

PTL 1: International Publication No. 2013/160978

### SUMMARY OF THE INVENTION

However, in the configuration described in PTL 1, it is necessary to branch the received input power to the rectifier unit side and the power measurement unit side at the measurement point. To directly branch a high-frequency signal such as input power, a circuit element such as a divider is used to branch the signal. However, there arises a problem that the influence of power loss increases as a power reception system because power is distributed by the divider and the power flowing into the rectifier unit decreases.

In addition, in the method of directly measuring the output power of a rectifier circuit, it is necessary to provide a current detection resistor and the like for measurement in the output unit of the rectifier circuit, which affects the output power of the rectifier circuit. In addition, it is necessary to measure a voltage value and a current value and multiply the voltage value and the current value to obtain the power. Thus, there is a problem that the influence of the loss of the direct-current power increases.

An object of the present disclosure is to provide a power reception apparatus and a received power estimation method capable of reducing an influence of a power loss.

A power reception apparatus according to the present disclosure includes:
a main rectifier circuit unit that rectifies received power and outputs rectified power to a load;
a sub rectifier circuit unit connected in parallel with a power reception unit of the main rectifier circuit unit; and
a measurement unit that measures power of an output unit of the sub rectifier circuit unit.

A received power estimation method according to the present disclosure is a method for estimating received power of a power reception apparatus, the power reception apparatus including a main rectifier circuit unit that rectifies received power and outputs rectified power to a load, and a sub rectifier circuit unit connected in parallel to a power reception unit of the main rectifier circuit unit, the method including:
measuring power of an output unit of the sub rectifier circuit unit; and
estimating output power of the main rectifier circuit unit based on a measurement result of the power.

According to the present disclosure, the influence of power loss can be reduced.

### BRIEF DESCRIPTION OF THE DRAWINGS

FIG. 1 is a diagram illustrating a configuration example of a wireless power transmission system to which a power reception apparatus according to an exemplary embodiment of the present disclosure is applied.

FIG. 2 is a diagram illustrating a configuration example of the power reception apparatus.

FIG. 3 is a diagram illustrating a configuration example of a main rectifier circuit unit and a sub rectifier circuit unit.

FIG. 4 is a diagram illustrating a relationship between received power and an output voltage measured in an experiment.

FIG. 5 is a flowchart illustrating an operation example of estimation control in a controller.

FIG. 6 is a diagram illustrating measurement results of rectification efficiency of a comparative example and a configuration according to the present exemplary embodiment.

### DESCRIPTION OF EMBODIMENT

### Exemplary Embodiment

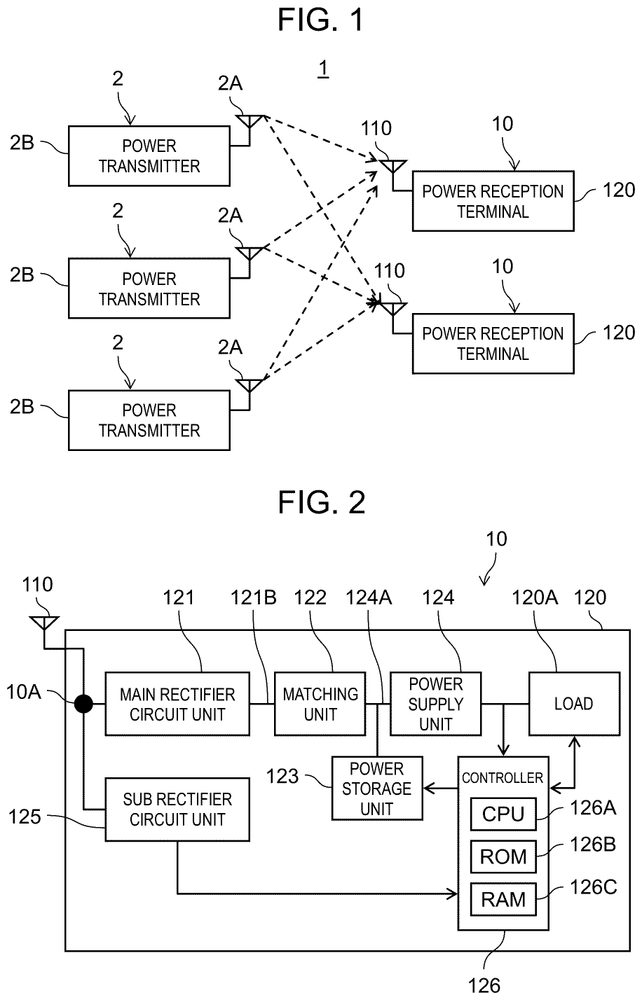

Hereinafter, an exemplary embodiment of the present disclosure will be described in detail with reference to the drawings. FIG. 1 is a diagram illustrating a configuration example of wireless power transmission system 1 to which power reception apparatus 10 according to the exemplary embodiment of the present disclosure is applied.

As illustrated in FIG. 1, wireless power transmission system 1 is a system capable of wirelessly transmitting power, and may be applicable to, for example, a system related to a microwave wireless power feeding technology. Wireless power transmission system 1 includes single or a plurality of power transmission apparatuses 2 and single or a plurality of power reception apparatuses 10.

Power transmission apparatus 2 is an apparatus that transmits power to power reception apparatus 10. Each of power transmission apparatuses 2 includes power transmission antenna 2A and power transmitter 2B, and may be capable of simultaneously transmitting power to each of a plurality of power reception apparatuses 10.

Power transmission apparatus 2 may be disposed on a ceiling or the like of a space in which power is transmitted, or may be disposed on a wall, a floor, or an installation object (for example, a desk or the like) in the space, for example. Power transmission apparatuses 2 may be disposed at equal intervals or may be disposed at random intervals. Power transmission apparatus 2 may have a fixed configuration or a configuration including a movement mechanism.

Power reception apparatus 10 is an apparatus that receives the power transmitted from power transmission apparatus 2. Each of power reception apparatuses 10 may be capable of simultaneously receiving power from power transmission apparatuses 2.

Power reception apparatus 10 includes power reception antenna 110 and power reception terminal 120. In power reception apparatus 10, the power transmitted from power transmission apparatus 2 is received by power reception antenna 110 and input to power reception terminal 120.

As illustrated in FIG. 2, power reception terminal 120 includes load 120A that exhibits a predetermined function. Load 120A is driven with power supply. The predetermined function is a function exhibited with power supply, and may be, for example, a sensor function for temperature and humidity, acceleration, electrocardiogram, and the like, a display function such as an LED or a liquid crystal, a communication function such as Bluetooth (registered trademark) low energy (BLE) communication, or the like.

For example, power reception terminal 120 is configured to be able to convert received power (for example, AC voltage) into power (for example, DC voltage) that can be supplied to load 120A and supply the converted power to load 120A. Power reception terminal 120 includes main rectifier circuit unit 121, matching unit 122, power storage unit 123, power supply unit 124, sub rectifier circuit unit 125, and controller 126.

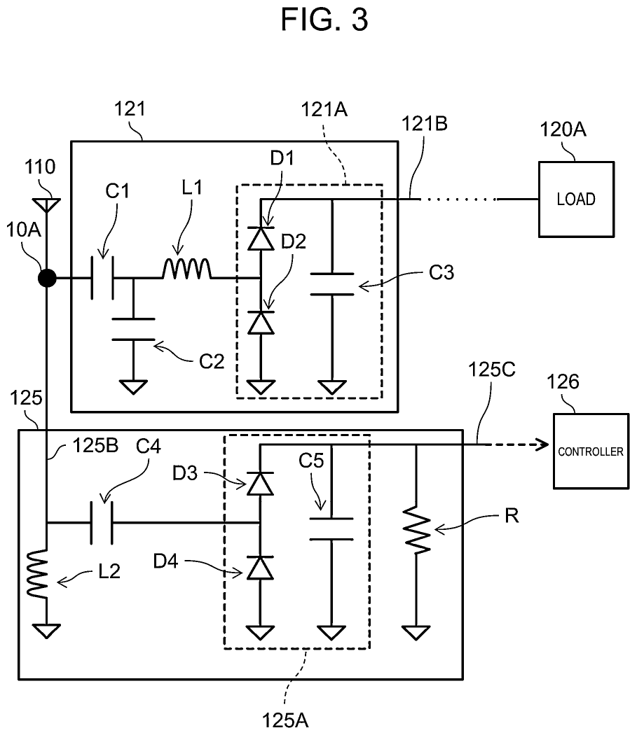

As illustrated in FIG. 3, main rectifier circuit unit 121 is a circuit unit that rectifies the received AC voltage and converts the received AC voltage into a DC voltage, and it includes first capacitor C1, inductor L1, second capacitor C2, and rectifier circuit 121A.

First capacitor C1 and inductor L1 are connected in series. First capacitor C1 is connected to power reception unit 10A connected to power reception antenna 110 on the side not connected to inductor L1, and inductor L1 is connected to rectifier circuit 121A on the side not connected to first capacitor C1. Inductor L1 does not have to be provided, and in such a case, the circuit is short-circuited.

Second capacitor C2 is provided between the ground and the wiring between first capacitor C1 and inductor L1. Second capacitor C2 does not have to be provided, and in such a case, the circuit is opened.

Rectifier circuit 121A may be, for example, a voltage doubler rectifier circuit, and it includes two diodes D1, D2 connected in series and third capacitor C3.

Diode D1 has an anode connected to a cathode of diode D2 and a cathode connected to first wiring 121B. The anode of diode D2 is connected to the ground. Third capacitor C3 is provided between first wiring 121B and the ground. First wiring 121B is an output wiring of main rectifier circuit unit 121.

Returning to FIG. 2, matching unit 122 performs impedance matching between main rectifier circuit unit 121 side and load 120A side by boosting or stepping down to reduce power reception loss such as reflection. Matching unit 122 is provided between first wiring 121B and second wiring 124A of main rectifier circuit unit 121. Second wiring 124A is an input wiring to power supply unit 124. Matching unit 122 may be, for example, a DC-DC converter or a charge pump.

Power storage unit 123 is provided between the ground and second wiring 124A on the output unit side of matching unit 122, and it stores the power (DC voltage) of second wiring 124A. Power storage unit 123 performs charging and discharging based on the received power.

For example, power storage unit 123 performs discharging to supplement power when the received power is insufficient for the driving of load 120A, and performs charging when the received power is sufficient for the driving of load 120A.

Power supply unit 124 is connected to second wiring 124A and generates input power (voltage) to load 120A based on the DC voltage from main rectifier circuit unit 121. Specifically, power supply unit 124 boosts or steps down the DC voltage from main rectifier circuit unit 121 to generate a voltage that can be supplied to load 120A.

As illustrated in FIG. 3, sub rectifier circuit unit 125 is a circuit unit that rectifies the received AC voltage and converts it into a DC voltage, and is connected to power reception unit 10A in parallel with main rectifier circuit unit 121. Sub rectifier circuit unit 125 includes fourth capacitor C4, inductor L2, rectifier circuit 125A, and resistor R. Resistor R does not have to be provided, and in such a case, the circuit is opened.

Fourth capacitor C4 is provided between third wiring 125B connected to power reception unit 10A and rectifier circuit 125A. Inductor L2 is provided between third wiring 125B and the ground. Inductor L2 does not have to be provided, and in such a case, the circuit is opened.

Rectifier circuit 125A has the same configuration as rectifier circuit 121A of main rectifier circuit unit 121, and it may be, for example, a voltage doubler rectifier circuit. Rectifier circuit 125A includes diodes D3, D4 connected in series and fifth capacitor C5.

Diode D3 has an anode connected to the cathode of diode D4 and a cathode connected to fourth wiring 125C. The anode of diode D4 is connected to the ground. Fifth capacitor C5 is provided between fourth wiring 125C and the ground. Resistor R is provided between fourth wiring 125C and the ground at the subsequent stage of rectifier circuit 125A in fourth wiring 125C. Fourth wiring 125C is an output wiring of sub rectifier circuit unit 125.

The input impedance of sub rectifier circuit unit 125 is larger than the input impedance of main rectifier circuit unit 121. The input impedance of sub rectifier circuit unit 125 is determined based on each parameter of fourth capacitor C4, inductor L2, and resistor R since rectifier circuit 125A has the same configuration as rectifier circuit 121A of main rectifier circuit unit 121.

In the present exemplary embodiment, since the input impedance of sub rectifier circuit unit 125 is larger than the input impedance of main rectifier circuit unit 121, the power loss of main rectifier circuit unit 121 can be reduced as compared with a configuration in which the main rectifier circuit unit and the sub rectifier circuit unit have the same input impedance.

The input impedance of sub rectifier circuit unit 125 is preferably larger than the input impedance of main rectifier circuit unit 121 as much as possible from the viewpoint of reducing the power loss of main rectifier circuit unit 121, and the input impedance is, for example, preferably more than or equal to 100 times, more preferably more than or equal to 1000 times the input impedance of main rectifier circuit unit 121. In particular, when the input impedance of sub rectifier circuit unit 125 is more than or equal to 1000 times the input impedance of main rectifier circuit unit 121, the power loss caused by sub rectifier circuit unit 125 in main rectifier circuit unit 121 can be reduced to a negligible level. Sub rectifier circuit unit 125 can be regarded as a CR parallel circuit in the fundamental wave because of the junction capacitance of the diode. Thus, it is possible to set the input impedance of sub rectifier circuit unit 125 higher than the input impedance of main rectifier circuit unit 121 by determining the parameter of inductor L2 so as to offset the capacitance components of diodes D3, D4.

The parameter of inductor L2 may be appropriately set according to the level at which the input impedance of sub rectifier circuit unit 125 is set.

Controller 126 includes central processing unit (CPU) 126A, read only memory (ROM) 126B, random access memory (RAM) 126C, and input/output circuit (see also FIG. 2).

Controller 126 measures the voltage (power) of the output unit of sub rectifier circuit unit 125 by monitoring the output voltage of fourth wiring 125C which is the output wiring of sub rectifier circuit unit 125. Controller 126 corresponds to a “measurement unit” of the present disclosure.

Controller 126 may measure the voltage (output voltage) of the output unit of sub rectifier circuit unit 125 with, for example, an A/D converter, a comparator, or the like. Controller 126 may estimate the received power amount based on the measurement result of the measured voltage. Controller 126 corresponds to an “estimation unit” of the present disclosure.

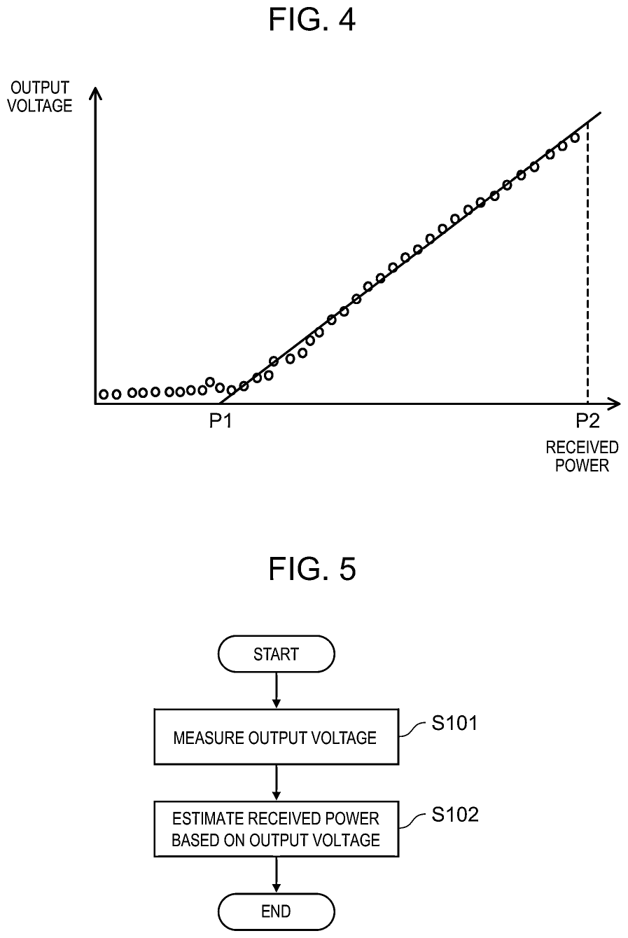

For example, controller 126 refers to a table indicating a relationship between the output voltage of sub rectifier circuit unit 125 and the received power, and estimates the received power amount based on the measured voltage of sub rectifier circuit unit 125. The table indicating the relationship between the output voltage and the received power may be calculated in advance by experiment, simulation, or the like as illustrated in FIG. 4, for example.

FIG. 4 is a diagram illustrating a relationship between the received power and the output voltage measured in an experiment. In FIG. 4, the vertical axis represents a logarithmic scale value (V) of the output voltage of sub rectifier circuit unit 125, and the horizontal axis represents received power (dBm).

FIG. 4 illustrates an experimental result performed by applying a predetermined frequency (for example, 920 MHz) to power reception point 10A using a signal generator and monitoring the output voltage of sub rectifier circuit unit 125 using a measuring instrument (for example, voltmeter). White circles in FIG. 4 indicate measured values of the output voltage corresponding to the received power value. In this experiment, the value of resistor R is set to 100 k2 considering that the input impedance of sub rectifier circuit unit 125 sufficiently increases.

For example, it can be confirmed that the output voltage has linearity on the double logarithmic graph within the range of received power P1 to P2 in FIG. 4. For example, a regression line (see the solid line in FIG. 4) between output voltage V (V) and input power P (mW) in the range from P1 to P2 can be calculated by using following Formula (1), and the received power amount can be estimated by using the regression line as, for example, a table indicating the relationship between the output voltage and the received power.

$$V = 0.2954 \times {P}^{0.8273} \qquad ( 1 )$$

Based on the estimation result of the received power, controller 126 may transmit the estimated value of the received power to power transmission apparatus 2 by, for example, BLE communication or the like, may control the matching ratio of matching unit 122, may perform charge/discharge control of power storage unit 123, may perform control of load 120A, data reception, and the like.

Next, an operation example of estimation control of received power with controller 126 will be described. FIG. 5 is a flowchart illustrating an operation example of estimation control in controller 126. The processing in FIG. 5 is appropriately started, for example, when power reception apparatus 10 receives the power transmitted from power transmission apparatus 2.

As illustrated in FIG. 5, controller 126 measures the output voltage of sub rectifier circuit unit 125 (step S101). After step S101, controller 126 estimates the received power based on the measurement result of the output voltage (step S102). After step S102, this control ends.

According to the present exemplary embodiment configured as described above, the power of the output unit of sub rectifier circuit unit 125 connected in parallel with the power reception unit of main rectifier circuit unit 121 is measured.

For example, conventionally, like the configuration described in PTL 1, a configuration is known in which received input power is branched into a rectifier unit side and a power measurement unit side at a measurement point to measure an input power amount. However, in this configuration, since a high frequency signal such as input power is directly branched, branching is performed using an element such as a divider. As a result, the power is distributed by the divider and the power flowing into the rectifier unit decreases, and thus there arises a problem that the influence of the power loss increases as the power reception system. In addition, in this configuration, since power is consumed to operate the power measurement element, the power consumption may also increase.

Specifically, when the element as described above is used, power of several mW is required to drive the element. Although depending on the reception distance, considering that the power that can be received by the power reception apparatus 10 is about several hundred μW, the power loss and the power consumption amount are greatly affected.

On the other hand, in the present exemplary embodiment, since the power of the output unit of sub rectifier circuit unit 125 connected in parallel with the power reception unit of main rectifier circuit unit 121 is measured, it is not necessary to use a dedicated power measuring element as in the configuration described in PTL 1. As a result, power for driving the element is not consumed, and thus the influence of the power loss can be greatly reduced. Further, since a part or all of the components constituting sub rectifier circuit unit 125 can be shared with main rectifier circuit unit 121, processes such as design, procurement, and evaluation are further simplified.

In addition, since power for operating the element is not consumed, the power consumption amount can be greatly reduced as compared with the configuration having the element.

In addition, conventionally, a method of directly measuring the output power of the rectifier unit is also conceivable, but in such a method, it is necessary to provide a measurement circuit or the like in the output unit of the rectifier unit, and thus, there is a problem that the output power of the rectifier unit is affected, and the influence of the loss of the DC power increases. In addition, in the measurement circuit, it is necessary to calculate power by independently measuring the current and the voltage, which may complicate the circuit.

On the other hand, in the present exemplary embodiment, the power of the output unit of sub rectifier circuit unit 125 is measured, and thus the output power of main rectifier circuit unit 121 is not affected. As a result, the influence of the loss of the output power of main rectifier circuit unit 121 can be reduced.

In addition, since the voltage of the output unit of sub rectifier circuit unit 125 is measured and the received power is estimated based on the voltage, it is not necessary to mount a complicated circuit. As a result, the configuration can be simplified, which can contribute to downsizing and cost reduction of power reception apparatus 10.

Since the input impedance of sub rectifier circuit unit 125 is larger than the input impedance of main rectifier circuit unit 121, the influence of the power loss can be reduced as compared with a configuration in which the input impedance of the sub rectifier circuit unit is less than or equal to the input impedance of the main rectifier circuit unit.

For example, when the input impedance of sub rectifier circuit unit 125 is about 1000 times the input impedance of main rectifier circuit unit 121, the influence of the power loss can be reduced to such an extent that the presence of sub rectifier circuit unit 125 can be ignored when viewed from power reception antenna 110 side.

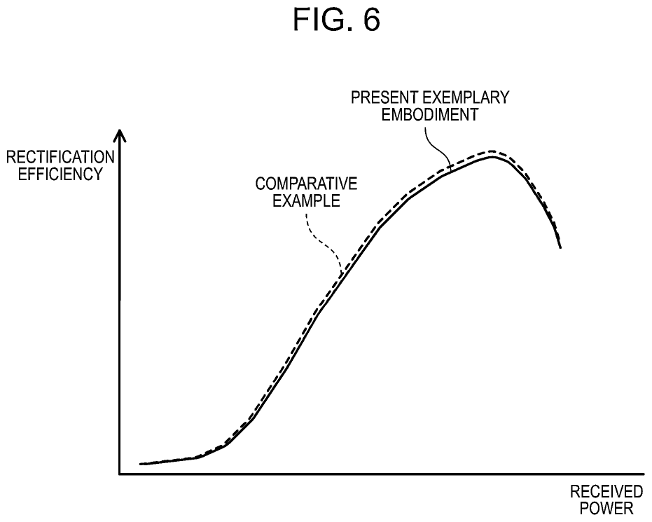

For example, FIG. 6 illustrates the measurement results of the rectification efficiency of the configuration without the sub rectifier circuit unit (comparative example) and the configuration according to the present exemplary embodiment. The measurement results illustrated in FIG. 6 are results obtained by experimentally measuring the rectification efficiency when the input power is varied in each of the comparative example and the present exemplary embodiment.

According to FIG. 6, it can be confirmed that substantially the same rectification efficiency is obtained over the entire range of the input power in the comparative example (broken line) and the present exemplary embodiment (solid line).

In addition, since sub rectifier circuit unit 125 is connected in parallel with main rectifier circuit unit 121, power reception apparatus 10 can have a simple configuration.

In addition, since it is not necessary to use an element for branching the received power, main rectifier circuit unit 121 and sub rectifier circuit unit 125 can be housed in one integrated circuit (IC). As a result, power reception apparatus 10 can be downsized as a whole.

The output voltage of sub rectifier circuit unit 125 is measured in the above exemplary embodiment, but the present disclosure is not limited to this configuration. The output current of sub rectifier circuit unit 125 may be measured. When the output current of sub rectifier circuit unit 125 is measured, the received power may be estimated based on the output voltage and the output current.

The voltage doubler rectifier circuit is a rectifier circuit in the above exemplary embodiment, but the present disclosure is not limited to this configuration. Another rectifier circuit such as a bridge-type rectifier circuit or a quadruple voltage rectifier circuit may be used.

The input impedance of sub rectifier circuit unit 125 is larger than the input impedance of main rectifier circuit unit 121 in the above exemplary embodiment, but the present disclosure is not limited to this configuration. The input impedance of the sub rectifier circuit unit 125 may be, for example, more than or equal to the input impedance of main rectifier circuit unit 121. However, from the viewpoint of reducing the power loss, it is preferable that the input impedance of sub rectifier circuit unit 125 is larger than the input impedance of main rectifier circuit unit 121.

The parameters of the capacitors, the inductors, the resistors, and the diodes in the above exemplary embodiment may be appropriately set according to the specifications and the like of power reception apparatus 10.

The above exemplary embodiment only shows a specific example of exemplary embodiments of the present disclosure. Therefore, it should not be understood that the above exemplary embodiment limits a technical scope of the present disclosure. That is, the present disclosure is applied in various forms without departing from a spirit of the present disclosure or essential features of the present disclosure.

### INDUSTRIAL APPLICABILITY

The power reception apparatus of the present disclosure is useful as a power reception apparatus and a received power estimation method capable of reducing the influence of power loss.

### REFERENCE MARKS IN THE DRAWINGS

1: wireless power transmission system
2: power transmission apparatus
2A: power transmission antenna
2B: power transmitter
10: power reception apparatus
110: power reception antenna
120: power reception terminal
121: main rectifier circuit unit
122: matching unit
123: power storage unit
124: power supply unit
125: sub rectifier circuit unit
126: controller

1. A power reception apparatus comprising:
a main rectifier circuit unit that rectifies received power and outputs rectified power to a load;
a sub rectifier circuit unit connected in parallel with a power reception unit of the main rectifier circuit unit; and
a measurement unit that measures power of an output unit of the sub rectifier circuit unit.

2. The power reception apparatus according to claim 1, wherein the sub rectifier circuit unit has an input impedance larger than an input impedance of the main rectifier circuit unit.

3. The power reception apparatus according to claim 1, wherein
the sub rectifier circuit unit includes:
a rectifier circuit including the output unit;
an inductor provided between the power reception unit and a ground; and
a capacitor including one end connected to the power reception unit and the other end connected to the rectifier circuit.

4. The power reception apparatus according to claim 1, wherein the measurement unit measures an output voltage of the sub rectifier circuit unit.

5. The power reception apparatus according to claim 1, the power reception apparatus further comprising an estimation unit that estimates output power of the main rectifier circuit unit based on a measurement result of the measurement unit.

6. The power reception apparatus according to claim 5, the power reception apparatus further comprising:
the load;
a matching unit that is provided between the main rectifier circuit unit and the load and performs impedance matching between the main rectifier circuit unit side and the load side;
a power storage unit that is provided at an output unit of the matching unit and performs charging and discharging according to the received power; and
a power supply unit that generates input power to the load based on the output power of the main rectifier circuit unit.

7. A method for estimating received power of a power reception apparatus, the power reception apparatus including a main rectifier circuit unit that rectifies received power and outputs rectified power to a load, and a sub rectifier circuit unit connected in parallel to a power reception unit of the main rectifier circuit unit, the method comprising:
measuring power of an output unit of the sub rectifier circuit unit; and
estimating output power of the main rectifier circuit unit based on a measurement result of the power.

8. The method for estimating received power according to claim 7, wherein the sub rectifier circuit unit has an input impedance larger than an input impedance of the main rectifier circuit unit.
